(19) United States
(12) Patent Application Publication
(10) Pub. No.: US 2024/0162389 A1
(43) Pub. Date: May 16, 2024

(54) DISPLAY DEVICE AND METHOD FOR MANUFACTURING DISPLAY DEVICE

(71) Applicant: SHARP KABUSHIKI KAISHA, Sakai City, Osaka (JP)

(72) Inventor: YUSUKE SAKAKIBARA, Sakai City, Osaka (JP)

(21) Appl. No.: 18/281,650

(22) PCT Filed: Apr. 6, 2021
(86) PCT No.: PCT/JP2021/014582

§ 371 Date: Sep. 12, 2023

(51) Int. Cl. H01L 33/50; H01L 25/075

(52) U.S. Cl. CPC H01L 33/502; H01L 25/0753

(57) ABSTRACT

Provided is a display device using a quantum dot including: a display portion including a plurality of pixels configured to display an image, each of the plurality of pixels including a light-emitting layer including the quantum dot, an anode electrode, and a cathode electrode; and a ligand formed at least in each of the plurality of pixels in an outer peripheral portion from an edge of a sealing layer formed on the display portion. Content of the ligands in the plurality of pixels of the same color is greater in the outer peripheral portion of the display portion than in a center portion of the display portion.

### TECHNICAL FIELD

The disclosure relates to a display device using quantum dots and a method for manufacturing the display device.

### BACKGROUND ART

It is known that a display device using quantum dots has low power consumption and excellent brightness and luminous efficiency.

For example, PTL 1 relates to a quantum dot light-emitting element and a method for manufacturing the same, and realizes a quantum dot light-emitting element having low turn-on voltage and drive voltage and excellent brightness and luminous efficiency by adjusting a band level of the quantum dot light-emitting layer by including a quantum dot light-emitting layer having an organic ligand distribution in which a surface in contact with a hole transport layer and a surface in contact with an electron transport layer are different from each other.

### CITATION LIST

### Patent Literature

PTL 1: JP 2010-114079 A

### SUMMARY OF INVENTION

### Technical Problem

However, generally, the quantum dots easily deteriorate due to oxygen and moisture. Since oxygen and moisture enter from a peripheral portion of a sealing layer over time and the quantum dots in an outer peripheral portion of a display portion in a display deteriorate faster than those in a center portion of the display portion, uneven brightness occurs between the center portion and the outer peripheral portion of the display portion in the display.

Therefore, in a device using the element described in PTL 1, since the content of ligand is not optimum for each position in the display, oxygen and moisture enter from the peripheral portion of the sealing layer over time to cause uneven brightness.

In view of the above problem, an object of the disclosure is to provide a display device that achieves low power consumption and a suppression in uneven brightness due to deterioration of quantum dots in a compatible manner.

### Solution to Problem

A display device according to an aspect of the disclosure is a display device using a quantum dot, the display device including: a display portion including a plurality of pixels configured to display an image, each of the plurality of pixels including a light-emitting layer including the quantum dot, an anode electrode, and a cathode electrode; and a ligand formed at least in each of the plurality of pixels in an outer peripheral portion from an edge of a sealing layer formed on the display portion, wherein content of the ligands in the plurality of pixels of the same color is greater in the outer peripheral portion of the display portion than in a center portion of the display portion.

A method for manufacturing according to an aspect of the disclosure is a method for manufacturing a display device, the display device using a quantum dot, and including a display portion including a plurality of pixels configured to display an image, each of the plurality of pixels including a light-emitting layer including the quantum dot, an anode electrode, and a cathode electrode; and a ligand formed at least in each of the plurality of pixels in an outer peripheral portion from an edge of a sealing layer formed on the display portion, the method including: forming at least a carrier transport layer on a substrate; and forming a ligand by immersing an outer peripheral portion at each side of the substrate in a solution containing the ligand, wherein in the forming a ligand, content of the ligands in pixels of the same color is greater in the outer peripheral portion of the display portion than in a center portion of the display portion.

### BRIEF DESCRIPTION OF DRAWINGS

FIG. 1 is a front view schematically illustrating a display device according to an embodiment of the disclosure.

FIG. 2 is a cross-sectional view illustrating a pixel in a center portion of a display portion.

FIG. 3 is a cross-sectional view illustrating a pixel in an outer peripheral portion of the display portion.

FIG. 4 is a front view illustrating an outer peripheral portion in which a ligand is formed in a pixel.

FIG. 5 is a front view illustrating a sealing layer formed on the display portion.

FIG. 6 is a diagram showing the relationship between the width of the outer peripheral portion and the contents of oxygen and moisture.

FIG. 7 is a diagram showing the relationship between service life and the contents of oxygen and moisture.

FIG. 8 is a diagram showing the relationship between the width of the outer peripheral portion and brightness.

FIG. 9 is a schematic diagram illustrating a method for manufacturing a display device according to an embodiment of the disclosure.

FIG. 10 is a diagram illustrating a power source line.

FIG. 11 is a diagram illustrating a pixel drive circuit.

FIG. 12 is a diagram showing that the content of the ligands decreases stepwise from the outer peripheral portion toward the center portion.

FIG. 13 is a diagram showing the content of the ligand when the pixel position is analyzed in the x direction of the display portion.

### DESCRIPTION OF EMBODIMENTS

Hereinafter, preferable embodiments of the disclosure will be described in detail with reference to the drawings. Note that the embodiments described below do not unduly limit the content of the disclosure described in the appended claims, and all of the configurations described in the present embodiments are not necessarily essential as resolution means of the disclosure.

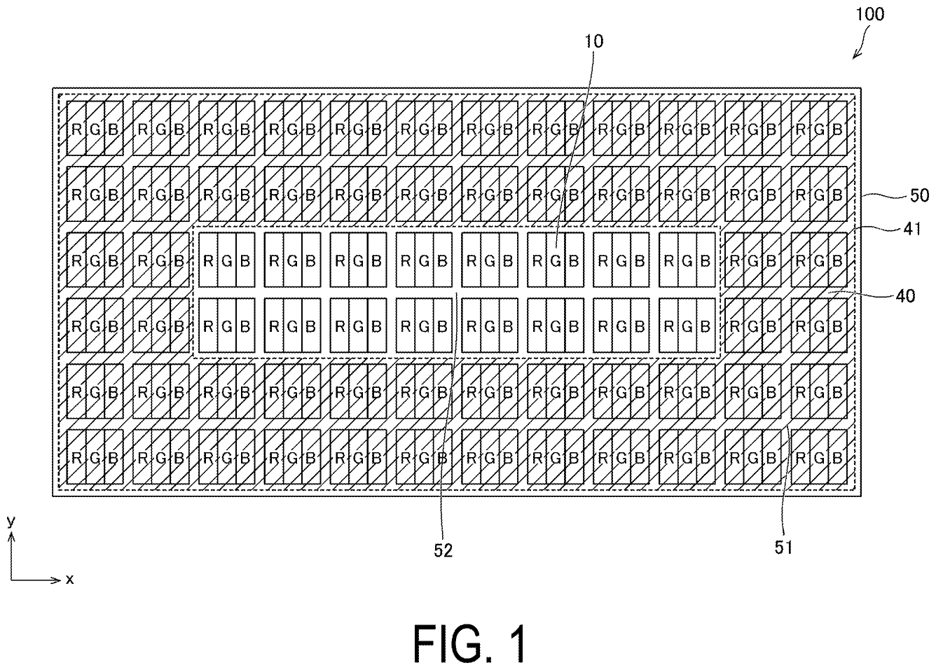

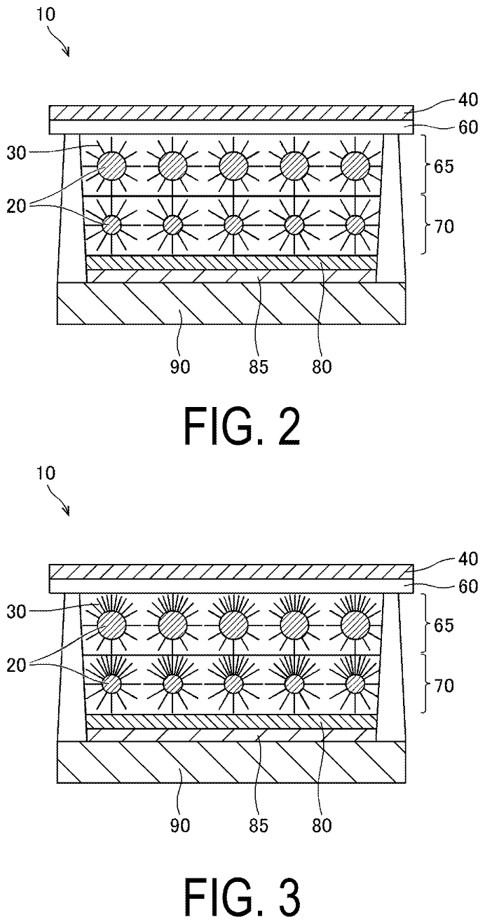

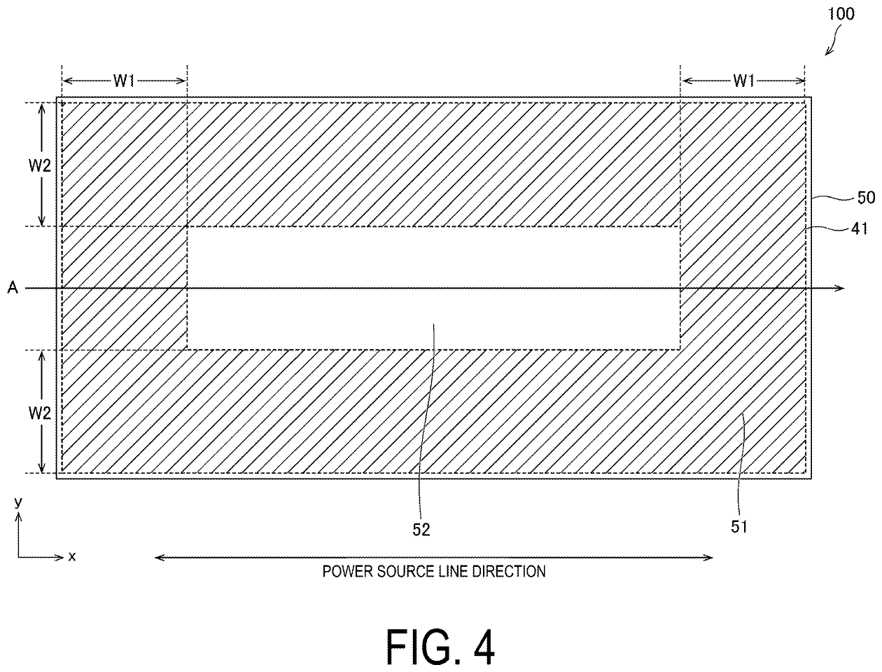

FIG. 1 is a front view schematically illustrating a display device 100 according to an embodiment of the disclosure. FIG. 2 is a cross-sectional view illustrating a pixel 10 in a center portion 52 of a display portion 50. FIG. 3 is a cross-sectional view illustrating the pixel 10 in an outer peripheral portion 51 of the display portion 50.

The display device 100 according to an embodiment of the disclosure is, for example, a quantum dot light emitting diode (QLED) display device. Hereinafter, it is assumed that the display device 100 is a QLED display device.

As illustrated in FIG. 1 to FIG. 3, the display device 100 according to an embodiment of the disclosure uses quantum dots 20, and includes the display portion 50 and a ligand 30. The display portion 50 includes a plurality of pixels 10 that display an image. Each of the plurality of pixels 10 includes a light-emitting layer 70 including the quantum dots 20, an anode electrode 85, and a cathode electrode 60. The ligand 30 is formed at least in the pixel 10 of the outer peripheral portion 51 from an edge 41 of a sealing layer 40 formed on the display portion 50. The content of the ligands 30 in the pixels 10 of the same color is greater in the outer peripheral portion 51 of the display portion 50 than in the center portion 52 of the display portion 50.

By forming more of the ligands 30 in the outer peripheral portion 51 than in the center portion 52, even when oxygen and moisture enter from the edge 41 of the sealing layer 40 over time, the ligands 30 protect the quantum dots 20, and uneven brightness due to deterioration of the quantum dots 20 is suppressed without complicating the manufacturing method. This is particularly effective when the display portion 50 has a narrow frame.

The pixel 10 configured to display an image includes the light-emitting layer 70 including the quantum dots 20, the anode electrode 85, and the cathode electrode 60, and may further include a substrate 90, a hole transport layer 80 on the substrate 90, and a carrier transport layer 65, as illustrated in FIGS. 2 and 3. Note that the light-emitting layer 70 including the quantum dots 20, the anode electrode 85, and the cathode electrode 60 may be provided on the substrate 90. The light-emitting layer 70, the anode electrode 85, the cathode electrode 60, the hole transport layer 80, and the carrier transport layer 65 may be surrounded by a bank made of an insulator to define the pixel 10.

The pixels R, G, and B emit red light, green light, and blue light respectively. The pixels R, G, and B may emit light of colors different from red, green, and blue, respectively.

The light-emitting layer 70 is formed of a blue light-emitting material, a green light-emitting material, and a red light-emitting material. Each light-emitting material of the blue light-emitting material, the green light-emitting material, and the red light-emitting material contains a quantum dot. The quantum dot is, for example, a semiconductor fine particle having a particle size of 100 nm or less. Examples of the semiconductor fine particle include at least one kind selected from the group consisting of a group II-VI compound, a group III-V compound, and a group IV compound. Examples of the group II-VI compound include at least one kind selected from the group consisting of MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe. Examples of the group III-V compound include at least one kind selected from the group consisting of GaAs, GaP, InN, InAs, InP, and InSb. Examples of the group IV compound include at least one kind selected from the group consisting of Si and Ge. The semiconductor fine particle may be a semiconductor fine particle composed of the crystal or may have a core/shell structure.

The anode electrode 85 and the cathode electrode 60 are each made of a conductive material. Examples of the conductive material include at least one kind selected from the group consisting of metal and transparent conductive oxide. Examples of the metal include at least one kind selected from the group consisting of Al, Cu, Au, and Ag. Examples of the transparent conductive oxide include at least one kind selected from the group consisting of Indium Tin Oxide (ITO), Indium Zinc Oxide (IZO), Zinc Oxide (ZnO), Aluminum Zinc Oxide (AZO), and Boron Zinc Oxide (BZO).

The hole transport layer 80 is formed of a hole transport material. The hole transport material includes, for example, at least one type selected from the group consisting of a hole transport inorganic material and a hole transport organic material. Examples of the hole transport inorganic material include at least one kind selected from the group consisting of metal oxide, metal nitride, and metal carbide. Examples of the metal include at least one kind selected from the group consisting of Zn, Cr, Ni, Ti, Nb, Al, Si, Mg, Ta, Hf, Zr, Y, La, Sr, and Mo. Examples of the hole transport material include at least one kind selected from the group consisting of 4,4′,4″-tris(9-carbazolyl)triphenylamine (TCTA), 4,4′-bis[N-(1-naphthyl)-N-phenyl-amino]-biphenyl (NPB), zinc phthalocyanine (ZnPC), di[4-(N,N-ditolylamino)phenyl]cyclohexane (TAPC), 4,4′-bis(carbazol-9-yl)biphenyl (CBP), 2,3,6,7,10,11-hexacyano-1,4,5,8,9,12-hexaazatriphenylene (HATCN), poly(N-vinylcarbazole) (PVK), poly(2,7-(9,9-di-n-octylfluorene)-(1,4-phenylene-((4-sec-butylphenyl)imino)-1,4-phenylene (TFB), a poly(triphenylamine) derivative (Poly-TPD), and poly(3,4-ethylenedioxythiophene)/poly(-styrenesulfonic acid) (PEDOT-PSS). The hole transport material may be a hole transport material made of one kind of substance, or a hole transport material made of a mixture of two or more kinds of substances.

The carrier transport layer 65 is formed of an electron transport material. Examples of the electron transport material include at least one kind selected from the group consisting of zinc oxide, titanium oxide, and strontium titanium oxide. The zinc oxide is, for example, ZnO. The titanium oxide is, for example, TiO₂. The strontium titanium oxide is, for example, SrTiO₃. The electron transport material may be an electron transport material made of one kind of substance or an electron transport material made of a mixture of two or more kinds of substances.

FIG. 4 is a front view illustrating the outer peripheral portion 51 in which the ligands 30 are formed in the pixel 10. As illustrated in FIG. 4, in the display device 100 according to an embodiment of the disclosure, the content of the ligands 30 in the pixels 10 of the same color is greater in the outer peripheral portion 51 of the display portion 50 than in the center portion 52. Note that the ligands 30 may be formed in both of the outer peripheral portion 51 and the center portion 52, and more of the ligands 30 may be formed in the outer peripheral portion 51. This makes it possible to protect the quantum dots 20 in the center portion 52 and further protect the quantum dots 20 in the outer peripheral portion 51. Alternatively, the ligands 30 may be formed only in the outer peripheral portion 51.

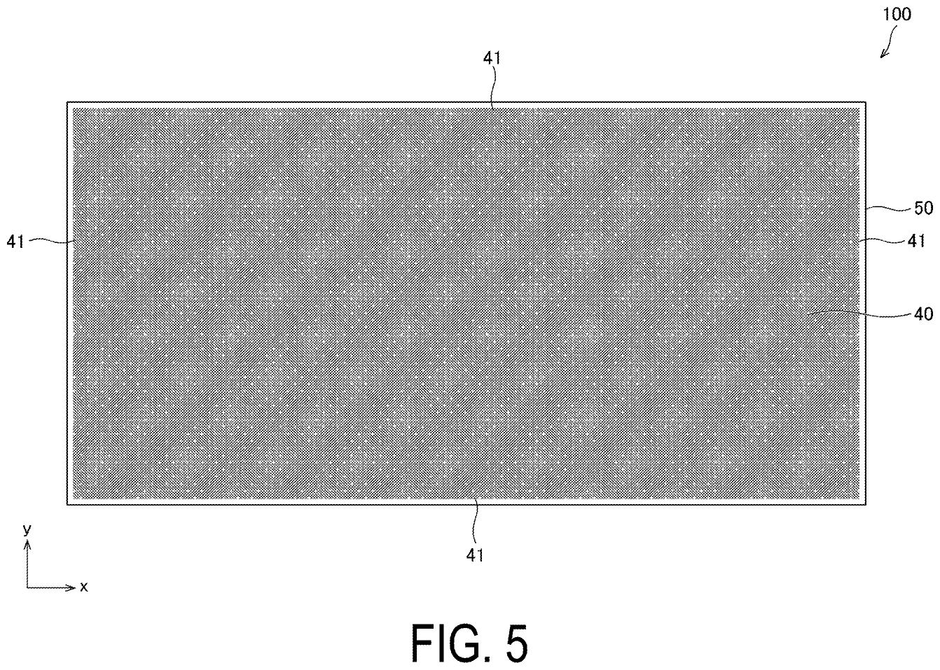

As illustrated in FIG. 5, the sealing layer 40 formed on the display portion 50 is formed on the entire surface of the display portion 50. The sealing layer 40 is formed on the entire surface of the substrate 90. The sealing layer is formed of a known material such as silicon oxide or silicon nitride.

Here, the outer peripheral portion 51 in which the ligands 30 are formed in the pixel 10 is the outer peripheral portion 51 of the display portion 50, and indicates a range from the edge 41 of the sealing layer 40 formed on the display portion 50 toward the center portion 52 of the display portion 50, which is a hatched range in FIG. 4.

The ligand 30 refers to a compound having the function to coordinate. The ligand 30 is considered to be coordinated in a case where both the ligand 30 and the quantum dot 20 are included.

In the display device 100 according to an embodiment of the disclosure, the content of the ligands 30 in the pixels 10 of the same color is greater in the outer peripheral portion 51 of the display portion 50 than in the center portion 52 of the display portion 50, thus achieving low power consumption and a suppression in uneven brightness due to deterioration of the quantum dots 20 in a compatible manner. This will be described in more detail below.

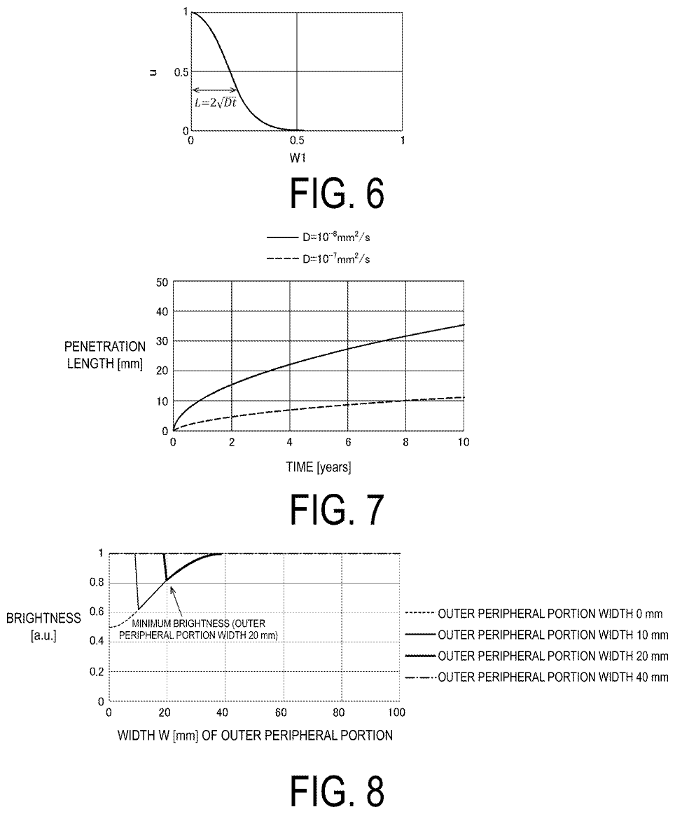

FIG. 6 is a diagram showing the relationship between a width W (W1, W2) of the outer peripheral portion 51 and the contents of oxygen and moisture. The width W (W1, W2) of the outer peripheral portion 51 from the edge 41 of the sealing layer 40 and the contents of oxygen and moisture u (W, t) at a time t follow the following diffusion equation.

$$\frac{δ u}{δ t} = D \frac{{δ}^{2} u}{δ {W}^{2}} \qquad [ Expression 1 ]$$

The solution to the above equation is given by the following equation.

$$u ( W 1 , t ) = \frac{1}{2 \sqrt{π Dt}} exp ( - \frac{{W}^{2}}{4 Dt} ) \qquad [ Expression 2 ]$$

Assuming that W at which u is 1/e is the penetration length L, FIG. 6 and the following equation are satisfied.

L=2\sqrt{Dt} [Expression 3]

FIG. 7 is a diagram showing the relationship between service life and the contents of oxygen and moisture. As shown in FIG. 7, D is about from 10⁻⁷ to 10⁻⁶ mm²/s, and the penetration depth at a lifetime of 10 years is from 11 to 36 mm. Therefore, the width W (W1, W2) of the outer peripheral portion 51 is preferably 11 mm or more from the edge 41 of the sealing layer 40, and more preferably 11 mm or more and 36 mm or less.

FIG. 8 is a diagram showing the relationship between the width W (W1, W2) of the outer peripheral portion 51 and brightness. Power consumption and brightness of the display device 100 will be described with reference to FIG. 8. First, the power consumption of the center portion 52 of the display portion 50 in which the ligands 30 are not formed in the pixel 10 is 1.00, and the brightness will be described later. The power consumption and the brightness of the outer peripheral portion 51 of the display portion 50 in which the ligands 30 are formed in the pixel 10 are 1.20 and 1.00, respectively. The display device 100 including the 40-inch display portion 50 is used as an example. In the display portion 50, y is 500 mm and x is 889 mm. Considering the area ratio, the power consumption of the display is given by:

1.00×(center portion area)+1.20×(outer peripheral portion area) [Equation 4]

Regarding the brightness, it is assumed that there is no deterioration of the quantum dots 20 due to oxygen and moisture in the outer peripheral portion in which the ligands 30 are formed, and the luminance is 1.00. In the center portion in which the ligands 30 are not formed, a decrease in brightness due to the deterioration of the quantum dots 20 due to oxygen and moisture is proportional to the contents of oxygen and moisture obtained by Expression 2, and the decrease in brightness at the distance x=0 from the edge portion is 0.50 (the brightness decreases by 0.50 from 1.00 to become 0.50). Note that, in this case, the penetration length L is 20 mm. At this time, the minimum brightness of the display is obtained at x=W. That is, the minimum brightness of the display is given by:

1.00−0.50×exp(−(W[mm]/20)²) [Equation 5]

In this way, the power consumption and the brightness are calculated in consideration of the area ratio between the center portion 52 and the outer peripheral portion 51. The results are shown in FIG. 8.

TABLE 1

| Outer peripheral | Area of | Area of outer | Power | |
|---|---|---|---|---|
| portion width | center | peripheral | consumption | Minimum |
| [mm] | portion | portion | (entire display) | brightness |
| 0 | 1.00 | 0.00 | 1.00 | 0.50 |
| 10 | 0.94 | 0.06 | 1.01 | 0.61 |
| 20 | 0.88 | 0.12 | 1.02 | 0.82 |
| 40 | 0.76 | 0.24 | 1.05 | 0.99 |
| 250 | 0.00 | 1.00 | 1.20 | 1.00 |

Note that the outer peripheral portion width being 0 mm refers to a case where the entire display portion is the center portion and the outer peripheral portion does not exist, and the outer peripheral portion width being 250 mm refers to a case where the entire display portion is the outer peripheral portion and the center portion does not exist.

As shown in FIG. 8 and Table 1, in a case in which the ligands 30 are not formed, the power consumption is 1.00 and the minimum brightness is 0.50. In such a case, although the power consumption is small, uneven brightness due to the deterioration of the quantum dots 20 cannot be suppressed.

Therefore, as shown in FIG. 8 and Table 1, as in the display device 100 according to an embodiment of the disclosure, the content of the ligands 30 is made greater in the outer peripheral portion 51 of the display portion 50 than in the center portion 52 of the display portion 50, thereby achieving low power consumption and a suppression in uneven brightness due to deterioration of the quantum dots 20 in a compatible manner. For example, by setting the width W (W1, W2) of the outer peripheral portion 51 to 40 mm, it is possible to maintain the minimum brightness at 0.99 while suppressing the power consumption to 1.05.

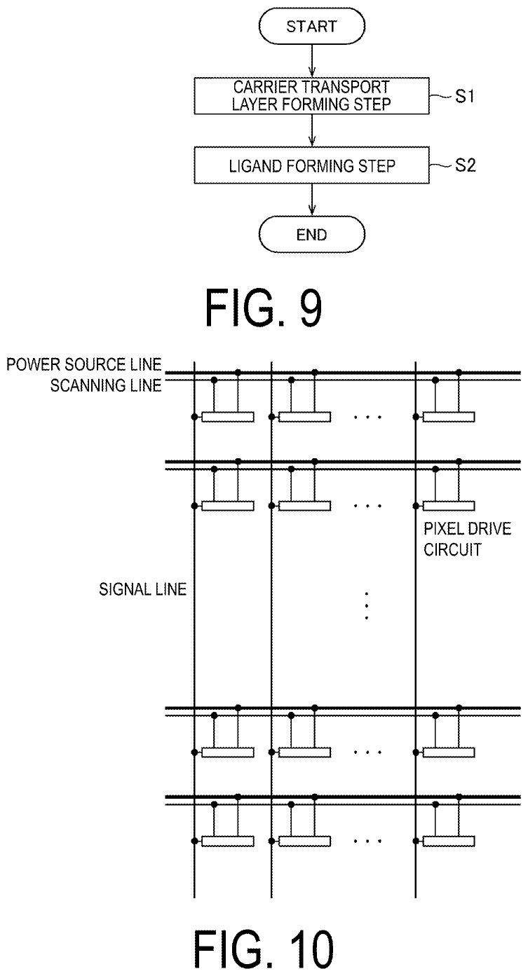

As illustrated in FIG. 9, a method for manufacturing the display device 100 according to an embodiment of the disclosure includes a carrier transport layer forming step S1 of forming at least the carrier transport layer 65 on the substrate 90, and a ligand forming step S2 of immersing the outer peripheral portion 51 at each side of the substrate 90 in a solution containing the ligands 30. First, the carrier transport layer 65 and/or the light-emitting layer 70 are formed on the substrate 90 in the carrier transport layer forming step S1. The layer(s) may be formed by a general film forming method such as coating, ink jet, vapor deposition, or sputtering. Then, in the ligand forming step S2, the substrate 90 is immersed by the width W (W1, W2) of the outer peripheral portion 51 at each side of the substrate 90 so that the content of ligands in the pixels of the same color is greater in the outer peripheral portion 51 of the display portion 50 than in the center portion 52 of the display portion 50. After the immersion, the substrate may be washed with a solvent such as methanol or ethanol to remove excess ligands. Further, the substrate may be heated to remove the solvent. For example, in a case in which the width W (W1, W2) of the outer peripheral portion 51 is 11 mm, each side of the substrate may be immersed in a ligand-containing solution to a depth of 11 mm (immersion in the ligand-containing solution can be repeated four times for each side). This forms the outer peripheral portion 51 in which the ligands 30 are formed.

Alternatively, the ligands may be added only to the outer peripheral portion 51 by covering the entire display portion 50 with a photoresist, exposing only the outer peripheral portion 51 to light to remove the photoresist only from the outer peripheral portion 51, and then immersing the entire display portion 50 in a solution containing the ligands 30. Thereafter, the photoresist remaining in the center portion 52 is exposed to light and removed.

A quantum dot having a core-shell structure may be used such that the quantum dot has a thicker shell thickness in the outer peripheral portion and a thinner shell thickness in the center portion. However, in such a case, it is necessary to use a plurality of quantum dots having shells with different thicknesses to separately pattern the outer peripheral portion and the center portion, which complicates the manufacturing method. As a method for preventing the deterioration of the quantum dot, a method of making it difficult for oxygen and moisture to enter by changing the panel structure, sealing material, or sealing method only in the outer peripheral portion of the display portion may be used. However, in this case, the structure and the manufacturing method become complicated. Therefore, according to the above-described manufacturing method, the content of the ligands 30 in the outer peripheral portion 51 can be easily increased without complicating the manufacturing method.

Hereinafter, a preferable aspect of the display device 100 according to an embodiment of the disclosure will be described.

As described above, the width W (W1, W2) of the outer peripheral portion 51 is preferably 11 mm or more from the edge 41 of the sealing layer 40, and more preferably 11 mm or more and 36 mm or less. In this way, the width W (W1, W2) of the outer peripheral portion 51 in which the ligands 30 are formed is optimized, thus achieving low power consumption and further suppression in uneven brightness due to deterioration of the quantum dots 20 in a compatible manner. The width W1 of the outer peripheral portion 51 in a y direction and the width W2 of the outer peripheral portion 51 in the x direction may be changed as appropriate.

As illustrated in FIGS. 2 and 3, the ligand 30 is preferably formed on the quantum dot 20. The quantum dot 20 is surrounded by ligand 30 molecules to block oxygen and moisture and protect the quantum dot 20. In this way, the ligand 30 protects the quantum dot 20 and suppresses uneven brightness due to further deterioration of the quantum dot 20.

The ligand 30 may be formed in the carrier transport layer 65 as illustrated in FIGS. 2 and 3. In this way, the carrier transport layer 65 can also be protected, thus achieving both low power consumption and a suppression in uneven brightness due to deterioration of the quantum dots 20 in a compatible manner. ZnO nanoparticles, ZnMgO nanoparticles, TiO₂ nanoparticles, or the like are used for the carrier transport layer 65.

As for the width W of the outer peripheral portion 51, the width W2 in a power source line direction can be made wider than the width W1 in a direction perpendicular to the power source line direction. Since the power source line is thicker than the signal line in order to supply a current, oxygen and moisture in the air are easily introduced. However, with the above configuration, it is possible to achieve low power consumption and further suppression in uneven brightness due to deterioration of the quantum dots 20 in a compatible manner. Now, the power source line and the pixel drive circuit will be described.

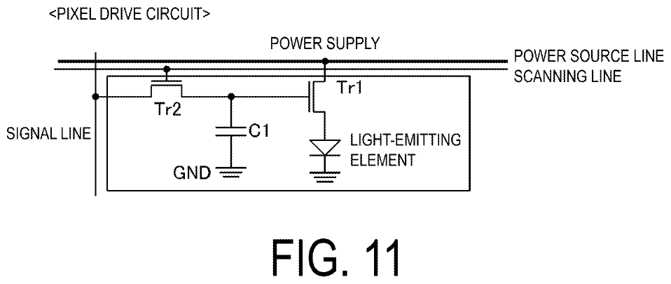

FIG. 10 is a diagram illustrating the power source line. FIG. 11 is a diagram illustrating the pixel drive circuit. As illustrated in FIG. 10 and FIG. 11, the pixel drive circuit includes, for example, a thin film transistor Tr1, a thin film transistor Tr2, and a capacitor C1. The thin film transistor Tr1 is a drive transistor configured to drive a light-emitting element. In the thin film transistor Tr1, a source electrode is connected to a power source line to which a voltage of a first level (e.g., a high level) is applied, a gate electrode is connected to a drain electrode of the thin film transistor Tr2 and one terminal of the capacitor C1, and a drain electrode is connected to the anode electrode of the light-emitting element. The thin film transistor Tr2 is a selecting transistor configured to select the light-emitting element to emit light in accordance with a scanning signal supplied from a scanning line. In the thin film transistor Tr2, the source electrode is connected to the signal line, the gate electrode is connected to the scanning line, and the drain electrode is connected to the gate electrode of the thin film transistor Tr1 and one terminal of the capacitor Cl. In the light-emitting element, the cathode electrode opposite to the anode electrode connected to the thin film transistor Tr1 and the other terminal of the capacitor C1 opposite to the one terminal are grounded by being connected to a GND line to which a voltage of a second level (e.g., a low level) is applied. When a scanning signal is supplied from the scanning line to the thin film transistor Tr2, the thin film transistor Tr2 is turned on, and a data signal is supplied from the signal line to the thin film transistor Tr1 via the thin film transistor Tr2. As a result, a current corresponding to the data signal flows through the light-emitting element, so that the light-emitting element emits light.

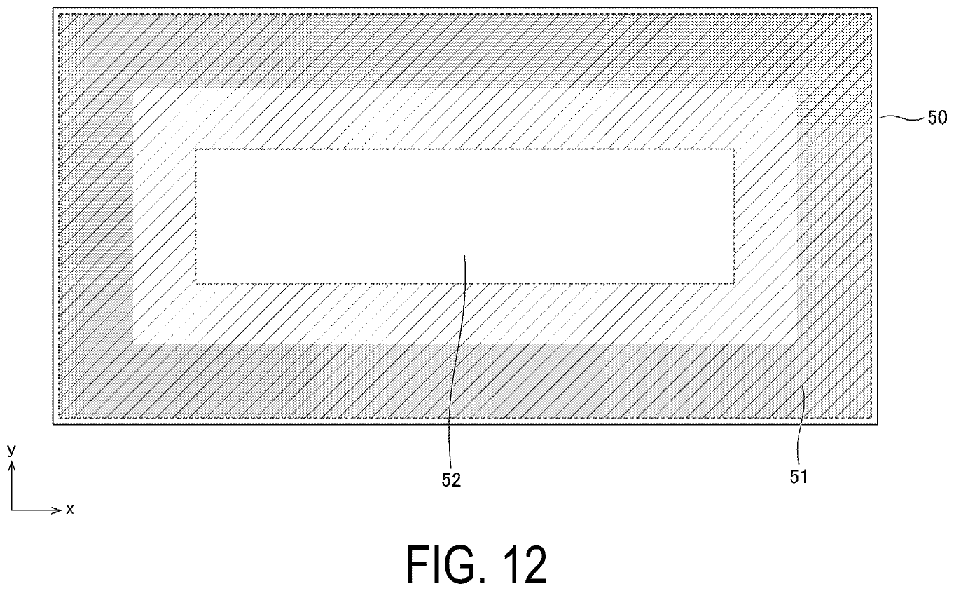

As illustrated in FIG. 12, the content of the ligands 30 can be decreased stepwise from the outer peripheral portion 51 toward the center portion 52. By changing the content of the ligands 30 formed on the display portion 50 stepwise, the width W (W1, W2) of the outer peripheral portion 51 in which the ligands 30 are formed is optimized, thus achieving low power consumption and further suppression in uneven brightness due to deterioration of the quantum dots 20 in a compatible manner.

The film thickness of the light-emitting layer 70 including the quantum dots 20 provided with the ligands 30 is preferably thinner in the outer peripheral portion 51 than in the center portion 52. With this configuration, the voltage of the display device 100 can be reduced, and the power consumption can be further reduced.

The molecule of the ligand 30 preferably contains one or more thiol groups. With this configuration, since S has a lower electronegativity than O and N, the hydrogen bond between the ligands 30 having a thiol group is lower than that having a hydroxyl group and an amino group, the ligand 30 easily becomes liquid at room temperature, and the ligand 30 can be easily formed on the display portion 50 in manufacturing.

The molecule of the ligand 30 preferably includes one thiol group. With this configuration, since the molecule of the ligand 30 becomes more polarized as the number of thiol groups increases, polar moisture molecules can be prevented from easily entering the inside of the pixel 10, the quantum dot 20 can be further protected by the molecule of the ligand 30, the ligand 30 easily becomes liquid at room temperature, and the ligand 30 can easily be formed on the display portion 50 in manufacturing.

The molecule of the ligand 30 preferably includes one or more thiol groups and a hydrocarbon. With this configuration, since the polarity of the portion other than the thiol group in the molecule of the ligand 30 decreases, polar moisture molecules can be prevented from easily entering the inside of the pixel 10, the quantum dot 20 can be further protected by the molecule of the ligand 30, the ligand 30 easily becomes liquid at room temperature, and the ligand 30 can easily be formed on the display portion 50 in manufacturing.

The number of carbon atoms per molecule of the ligand 30 is preferably from 8 to 18. With this configuration, when the number of carbon atoms is from 8 to 18, the molecule of the ligand 30 becomes long, the quantum dot 20 can be further protected, the ligand 30 easily becomes liquid at room temperature, and the ligand 30 can easily be formed on the display portion 50 in manufacturing. An example of a compound having 8 carbon atoms is octanethiol (melting point: −49° C.), an example of a compound having 12 carbon atoms is dodecanethiol (melting point: −7° C.), and an example of a compound having 18 carbon atoms is octadecanethiol (melting point: 30 to 33° C.). The ligand 30 can include a halogen such as fluorine, chlorine, bromine, or iodine. The halogen has a strong coordination force relative to the quantum dot 20 and can more strongly protect the quantum dot 20.

Next, an analysis method for confirming that the content of the ligands 30 is greater in the outer peripheral portion 51 of the display portion 50 than in the center portion 52 of the display portion 50 will be described.

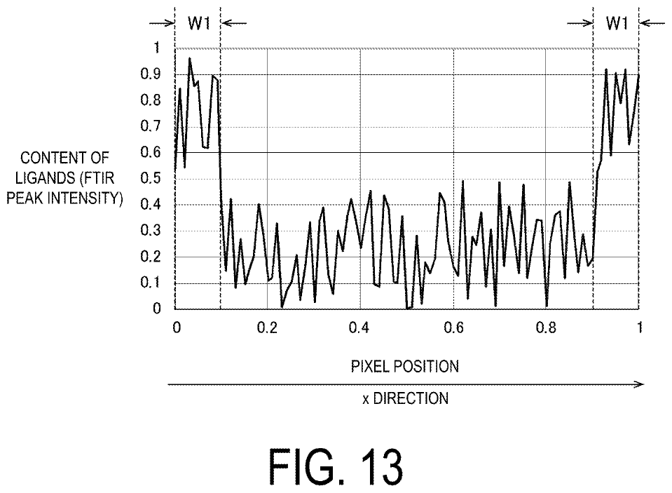

FIG. 13 is a diagram showing the content of the ligands 30 when the pixel position is analyzed in the x direction of the display portion 50, and shows the result of one line analysis of the pixels 10 of the same color in the A direction in FIG. 4. FIG. 13 shows the result of FTIR analysis and shows the peak intensity of a specific functional group (e.g., thiol group). As shown in FIG. 13, it can be seen that the peak intensity of the ligands in the width W1 of the outer peripheral portion 51 is higher than that in the center portion 52, and the content of the ligands 30 is greater. As described above, confirmation of the content of the ligands 30 can be specified by the FTIR peak intensity by analyzing one row of the pixels 10 of the same color using FTIR. The direction of analysis is not limited to the x direction, and analysis may be performed in the y direction or along a diagonal line.

Although in the above description the peak intensity of the thiol group is measured, the peak intensity derived from a specific ligand 30 other than the thiol group may be measured, identification may be performed with reference to various databases or the like, or identification may be performed by measuring the ligand 30 alone.

The content of the ligands may be confirmed by a method other than FTIR, such as NMR, two-dimensional NMR, XPS, EDX, TGA, or ICP.

In NMR, the ligand on the surface of the quantum dot 20 is specified from ¹HNMR, ³¹PNMR, and ¹³CNMR. Based on the chemical shift and line width, it is possible to distinguish between ligands that are bonded to the quantum dot 20 and ligands that are not bonded to the quantum dot 20.

The two-dimensional NMR is a method useful when the one-dimensional NMR cannot distinguish between bonded and not bonded ligands from DOSY and NOESY.

The XPS can distinguish whether or not the ligand 30 is bonded to the quantum dot 20. The coverage rate can be calculated by calculating the ratio between the element of the core of the quantum dot 20 and the element of the ligand 30 bonded thereto.

The EDX can confirm what element is included in the ligand 30. Elements that can be measured are limited (atomic number 11 or higher).

The TGA can determine the total content of the ligands 30 contained in a sample of the quantum dots 20 by the difference in decomposition temperature between the ligand 30 and the core.

In the ICP, since N, P, and S are not easily ionized, it is difficult to perform elemental analysis on the ligand 30.

In this way, it is confirmed that the content of the ligands 30 is greater in the outer peripheral portion 51 of the display portion 50 than in the center portion 52 of the display portion 50.

As described above, the disclosure makes it possible to provide the display device 100 that achieves low power consumption and a suppression in uneven brightness due to deterioration of the quantum dots 20 in a compatible manner.

Although embodiments and examples of the disclosure have been described in detail above, it will be readily understood by those having skill in the art that many modifications can be made without substantially departing from the novel matters and effects of the disclosure. Therefore, all such modifications are included in the scope of the disclosure.

For example, a term described at least once together with a different term having a broader meaning or the same meaning in the specification or the drawings can be regarded as the different term in any place in the specification or the drawings. The configuration and operation of the display device and the method for manufacturing the display device are not limited to those described in the embodiments and examples of the disclosure, and various modifications can be made.

1. A display device using a quantum dot, the display device comprising:
a display portion including a plurality of pixels configured to display an image, each of the plurality of pixels including a light-emitting layer including the quantum dot, an anode electrode, and a cathode electrode; and
a ligand formed at least in each of the plurality of pixels in an outer peripheral portion from an edge of a sealing layer formed on the display portion,
wherein content of the ligands in the plurality of pixels of the same color is greater in the outer peripheral portion of the display portion than in a center portion of the display portion.

2. The display device according to claim 1,
wherein a width of the outer peripheral portion is 11 mm or more from the edge of the sealing layer.

3. The display device according to claim 1,
wherein the width of the outer peripheral portion is 11 mm or more and 36 mm or less from the edge of the sealing layer.

4. The display device according to claim 1,
wherein the ligand is formed in the quantum dot.

5. The display device according to claim 1,
wherein each of the plurality of pixels further includes a carrier transport layer, and
the ligand is formed in the carrier transport layer.

6. The display device according to claim 1,
wherein the width of the outer peripheral portion in a power source line direction is wider than the width of the outer peripheral portion in a direction perpendicular to the power source line direction.

7. The display device according to claim 1,
wherein the content of the ligands decreases stepwise from the outer peripheral portion toward the center portion.

8. The display device according to claim 4,
wherein a film thickness of a light-emitting layer including the quantum dot provided with the ligand is thinner in the outer peripheral portion than in the center portion.

9. The display device according to claim 1,
wherein a molecule of the ligand includes one or more thiol groups.

10. The display device according to claim 1,
wherein the molecule of the ligand includes one thiol group.

11. The display device according to claim 1, wherein the molecule of the ligand includes one or more thiol groups and a hydrocarbon.

12. The display device according to claim 1,
wherein the number of carbon atoms per molecule of the ligand is from 8 to 18.

13. A method for manufacturing a display device, the display device using a quantum dot and including a display portion including a plurality of pixels configured to display an image, each of the plurality of pixels including a light-emitting layer including the quantum dot, an anode electrode, and a cathode electrode; and a ligand formed at least in each of the plurality of pixels in an outer peripheral portion from an edge of a sealing layer formed on the display portion, the method comprising:
forming at least a carrier transport layer on a substrate; and
forming a ligand by immersing an outer peripheral portion at each side of the substrate in a solution containing the ligand,
wherein in the forming a ligand, content of the ligands in pixels of the same color is greater in the outer peripheral portion of the display portion than in a center portion of the display portion.
